(19) United States
(12) Patent Application Publication
(10) Pub. No.: US 2025/0342289 A1
(43) Pub. Date: Nov. 6, 2025

(54) Method for validating digitally manipulated (augmented) test scenarios

(71) Applicant: AVL Software and Functions GmbH, Regensburg (DE)

(72) Inventors: Justus HOFMEISTER, Regensburg (DE); Tino KEREJEWSKI, Regensburg (DE)

(73) Assignee: AVL Software and Functions GmbH, Regensburg (DE)

(21) Appl. No.: 19/089,424

(22) Filed: Mar. 25, 2025

(30) Foreign Application Priority Data
May 2, 2024 (DE) 102024112338.9

(51) Int. Cl. G06F 30/20

(52) U.S. Cl. CPC G06F 30/20

(57) ABSTRACT

The invention relates to a method for validating digitally manipulated (augmented) test scenarios, comprising the steps of digitally recording a basic scenario with at least one real vehicle travelling on a real track under defined real traffic conditions; digitally recording the basic scenario manipulated by selected traffic conditions to create a reference scenario; manipulating the data of the digitally recorded base scenario by selected traffic conditions to create an extended test scenario; acquiring data of the traffic conditions in the extended test scenario and data in the reference scenario with at least one sensor; analysing the correlation between the test and reference data acquired with the at least one sensor, and evaluating a validity of the data of the test scenario based on a result of the analysing of the correlation. The invention further relates to a corresponding computer-implemented method and preferred uses of the method.

The invention relates to the technical field of simulation engineering and in particular to a method for validating digitally manipulated (augmented) test scenarios according to claim 1, to a corresponding computer-implemented method according to claim 10, and to preferred uses of the method according to claim 15.

The validation of functions for sensing environmental data for automated driving systems (ADS) requires a great deal of testing, including the use of simulated or recorded test data (test stimuli) from various scenarios. Sensor algorithms in the sense of the ‘sense-plan-act’ division of automated driving stacks are taken into account in all aspects of the acquisition and processing of environmental information. As simulations are currently not sufficiently representative, real recordings based on open world driving and/or test sites can usually be used. The collection of real data involves a great deal of effort and is heavily dependent on parameters that cannot be influenced, such as weather or lighting conditions.

One task of the present invention is therefore to circumvent these disadvantages and provide realistic and easy-to-produce test data for simulating autonomous vehicles.

This task is solved by a method for validating digitally manipulated (augmented) test scenarios according to claim 1. The method according to the invention comprises the steps of digitally recording a basic scenario with at least one real vehicle travelling on a real track under defined real traffic conditions; digitally recording the basic scenario manipulated by selected traffic conditions to create a reference scenario; manipulating the data of the digitally recorded basic scenario by selected traffic conditions to create an augmented test scenario; acquiring data of the traffic conditions in the extended test scenario and data in the reference scenario with at least one sensor; analysing the correlation between the test and reference data acquired with the at least one sensor; and evaluating a validity of the data of the test scenario based on a result of analysing the correlation.

Analysing the correlation between the test and reference data recorded by the at least one sensor can also include comparing a system behaviour after applying the test stimuli (real/digital) to an ADS. In this case, the extent to which the detection functions for recording environmental data lead to the same system behaviour is checked.

A key point of the method according to the invention is to maximise the use of the recorded real data by digitally manipulating or augmenting the available data in relation to certain parameters. In this ‘data augmentation’, the real recording is manipulated in such a way that individual parameters are changed in order to generate additional instances of the recorded data. This process significantly increases the available test data at a reasonable cost.

The subclaims set out further advantageous embodiments of the method according to the invention.

In a first advantageous embodiment of the method according to the invention, it is provided that the traffic conditions comprise weather conditions, such as precipitation, light conditions, and/or road conditions, such as the type, course and nature of a road, objects such as vehicles or persons, regulations such as traffic signs or light signals. This allows a wide variety of test scenarios to be developed and analysed against reference scenarios.

In a second preferred embodiment of the method according to the invention, the selected traffic conditions comprise adding the effect of precipitation, in particular fog, drizzle, rain showers, sleet and/or snow, thus providing a range of precipitation which usually poses a particular challenge to the detection functions of a vehicle for avoiding critical driving situations.

In a further preferred embodiment of the method according to the invention, a digital noise and brightness changes are added to generate the effect of selected traffic conditions, which in particular allows a particularly simple simulation of precipitation.

In principle, all weather conditions can be simulated. However, it is also advantageous if the selected traffic conditions include the addition of the effect of other objects, such as other vehicles and/or people, in order to allow simulations of specific traffic conditions.

In a further preferred embodiment of the method according to the invention, the digitised recording of the base and/or reference scenario comprises imaging and/or distance data, which are produced in particular by camera images and/or LIDAR (Light Detection And Ranging) point clouds and/or radar (Radio Detection And Ranging). This provides particularly accurate reference data that improves the analysis of the test scenario.

In a further preferred embodiment of the method according to the invention, an evaluation (validation) of the validity of the data of the test scenario is carried out based on the analysis of the correlation between the data of the test scenario and those of the reference scenario. This makes it possible to determine the extent to which the data of the test scenario can actually be used for a simulation of real traffic conditions.

In a further preferred embodiment of the method according to the invention, the validity of the test scenario data is assessed in accordance with the ISO 21448-2022 standard (scenario and system analysis), which allows the test data to be assessed according to a defined standard that also allows subsequent certification of the simulation and/or the detection functions.

To validate the data of the test scenario, an assessment of its validity, as described above, is taken into account. In order to finally bring the test scenario closer to the reference scenario, in a further preferred embodiment of the method according to the invention, the data of the selected traffic conditions are then manipulated (optimised) accordingly on the basis of this evaluation of the data of the test scenario.

On the one hand, the test scenario can be optimised as described above. However, if the test scenario and reference scenario match sufficiently, for example because the test data can be validly assessed according to standard ISO 21448-2022, it is preferable to also manipulate detection-related algorithms of the at least one sensor for autonomous vehicles in order to improve the detection performance of the at least one sensor.

The foregoing problem is also solved by a computer-implemented method for validating digitally manipulated (augmented) test scenarios according to claim 10, wherein a computer communicates with at least one image and/or distance providing sensor to record a base and reference scenario, and manipulates the base scenario by selected traffic conditions to create an augmented test scenario, and communicates with the at least one sensor to record data of the traffic conditions in the reference scenario and the extended test scenario, and analyses and evaluates a correlation between the data recorded by the at least one sensor in the test scenario and the reference data of the traffic conditions recorded by the at least one sensor in the reference scenario.

A key point of the computer-implemented method according to the invention is that it can be largely automated and thus has a considerable time advantage over conventional open world drives and/or test sites.

Advantageous further embodiments of the computer-implemented method according to the invention are given in the sub-claims.

In a first preferred embodiment of the computer-implemented method, compliance with the ISO 21448-2022 standard (scenario and system analysis) is determined for evaluating (150) the validity of the test scenario data, which allows compliance with defined standards and, subsequently, corresponding certification of an autonomous vehicle.

In a second preferred embodiment of the computer-implemented method, the data of the selected traffic conditions are manipulated on the basis of the assessment of the validity of the data of the test scenario, which enables this step to be automated with a further time advantage and a defined validation of this data.

In a further preferred embodiment of the computer-implemented method, detection-related algorithms of the at least one sensor for autonomous vehicles are manipulated on the basis of the analysis. This is done in particular if the data of the test scenario is evaluated as valid and the detection performance of the at least one sensor is to be further optimised.

In a further preferred embodiment of the computer-implemented method, optimisation of the test scenario and/or detection-related algorithms of the at least one sensor is supported by a self-learning algorithm, in particular based on machine learning and/or neural networks. This means that a time advantage can also be achieved in this optimisation step, which can be attributed to self-learning systems.

In principle, the method according to the invention can be used to simulate a wide range of different traffic conditions. For this very reason, it should preferably be used to optimise extended test scenarios for the optimisation of sensors and/or extended test scenarios for autonomous driving systems.

Further advantages, objectives and features of the present invention are explained with reference to the following description of the attached figures. Similar components may have the same reference signs in the various embodiments. It shows:

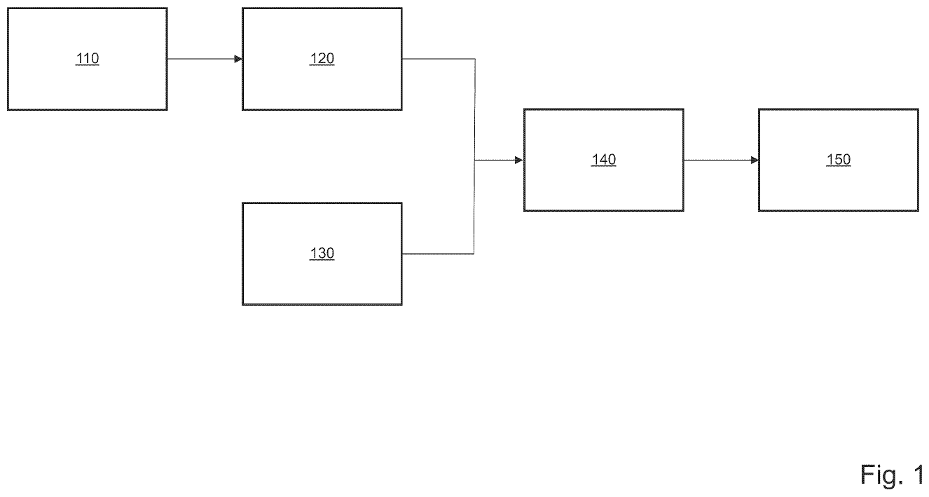

FIG. 1 a functional diagram of a method sequence according to the invention for validating digitally manipulated (augmented) test scenarios;

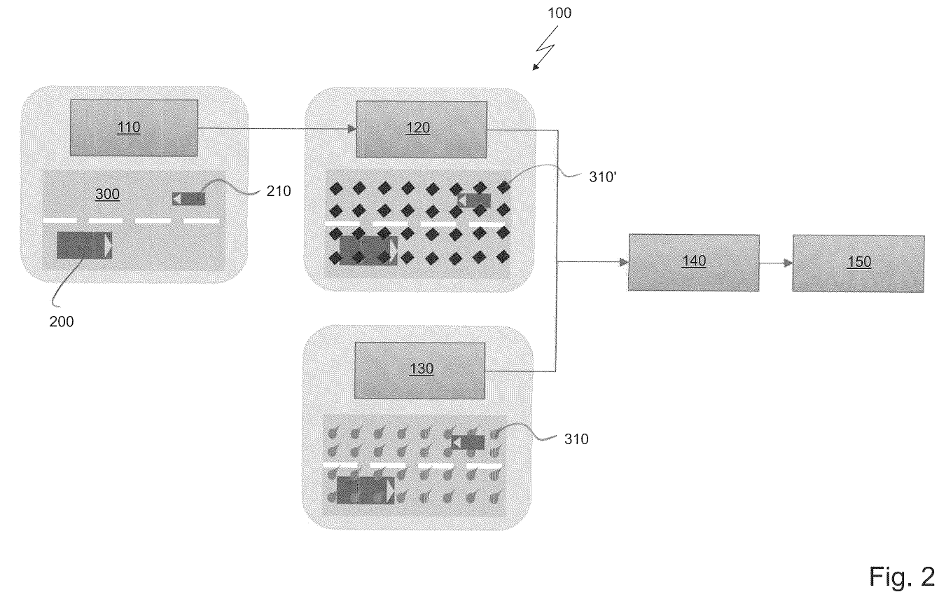

FIG. 2 a more detailed representation of the objects of all steps of the method sequence according to FIG. 1, and

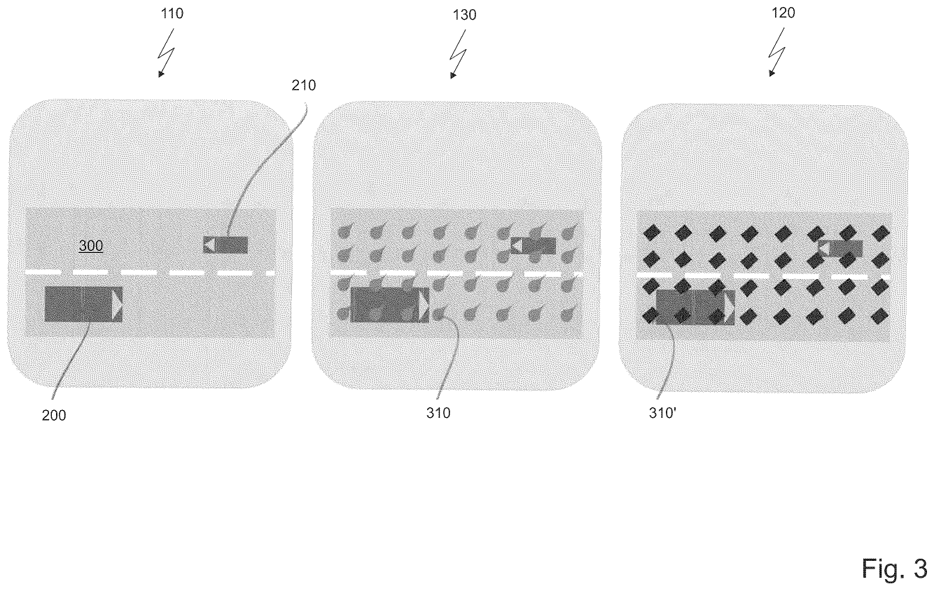

FIG. 3 a comparison of the objects in the base, test, and reference scenarios.

FIG. 1 shows a functional diagram of a method sequence 100 according to the invention for validating a digitally manipulated (augmented) test scenario 120. In step 110, a real basic scenario of traffic conditions is digitally recorded and, in a subsequent step 120, digitally augmented to form a test scenario. In this process, a parameter x of the data of the digital test scenario is changed by expanding it to a specific value. The real basic scenario 110 is digitally recorded as the reference scenario 130, but this has been changed with the parameter x to the same specific traffic conditions as for the extended test scenario 120. In a further step 140, the correlation between the test stimuli of the test scenario 120 and the data of the reference scenario 130 is analysed, and the validity of the extended test data is subsequently evaluated. The system behaviour after application of the test stimuli (real/digital) to an ADS is also compared here, i.e. the extent to which the detection functions for recording environmental data lead to the same system behaviour is checked. If these are considered valid, for example with regard to the SOTIF (Safety Of The Intended Functionality) validation of the ISO 21448-2022 standard, the test scenario can be used for the simulation of a sensor, in particular for an imaging and/or distance-measuring sensor. A specific detection system is therefore required for this validation approach.

The validation approach is therefore based on the use of a real test environment with high reproducibility. For validation, the correlations between almost identical scenarios are analysed both in the real world and with extended data. The validation argument and the evidence for data augmentation with respect to specific parameters in representative scenarios can be used as evidence in a generalised validation argument for augmented data.

The data augmentation mechanism is a key mechanism for the multiplication of existing real recorded data for the validation of sensor algorithms. In order to use this mechanism for SOTIF validation according to the ISO 21448-2022 standard, an argument for the validity and adequacy, including proof of the mechanism, must be presented. The validation approach described above strongly supports the SOTIF argument and is a valuable product in the context of autonomous driving in the European market, as well as a safety argument in the context of autonomous driving in the international market.

FIG. 2 shows a more detailed representation of the objects of all the steps of the method sequence according to FIG. 1. In step 110, to form a digital base scenario, a track 300 with an EGO (autonomous) vehicle 200 in one lane and a PRU (protected road user), in this case a vehicle 210 in a parallel lane, moving towards each other is created. In the further step 120, a test scenario is created by digital enhancement of selected traffic conditions 310′, here precipitation by adding digital and noise and brightness reduction. Finally, in the step 130, a reference scenario with digitally recorded selected traffic conditions 310, in this case real precipitation, is recorded for comparison with the test scenario.

In the next step 140, a correlation between the test stimuli of the test scenario and the data of the reference scenario is analysed, and the validity of the data is evaluated in the subsequent step 150. If, for example, the data is invalid compared to standard ISO 21448-2022, the data does not realistically reflect the selected real traffic conditions. The data would therefore need to be optimised, for example by manipulating the digital noise and brightness accordingly. This process can also be supported by self-learning systems such as neural networks, whose training data includes the extended data of the test scenario and the data of the reference scenario.

In principle, real recordings such as camera images and/or LIDAR point clouds of a scenario in slightly cloudy weather conditions can serve as the basic scenario. Digital noise and changes in brightness are added to this recorded data to create the effect of rain or fog in the test scenario. This results in a case of the base scenario with altered weather conditions.

A corresponding method involves digitally recording a base scenario without precipitation in open world drives and/or test sites. Then a reference scenario, exactly the same scenario as the base scenario with a certain amount of precipitation, is digitally recorded in open world drives and/or test sites. Finally, the recorded base scenario (without precipitation) is extended by adding digital noise to simulate precipitation. Finally, the correlation between the reference scenario and the extended baseline scenario is analysed to assess the validity of the extension.

However, real recordings can also serve as a basis, such as camera images and/or LIDAR point clouds of an intersection-related scenario with a PRU such as a vehicle. The information representing the PRU, in the case of the camera the pixels, in the case of the LIDAR the point cloud partition, can be extracted and reinserted into the scenario at a different position in order to simulate another PRU within the scenario. This creates another instance of the base scenario with an additional PRU.

A corresponding method in this case is to digitally record a basic scenario with a vehicle n metres in front of the EGO vehicle, in the middle of the oncoming lane, in open world driving and/or proving grounds. Then a reference scenario, exactly the same as the base scenario, is digitally recorded, but with the vehicle centred on the centre lane marker in open world driving and/or proving grounds. Finally, the recorded base scenario is extended by virtually/digitally moving the vehicle in the centre of the centre lane marking to simulate object movement. Finally, a correlation between the reference scenario and the extended base scenario is analysed to assess the validity of the extension.

FIG. 3 shows a comparison of the objects of the basic, test and reference scenarios from steps 110, 120 and 130. The EGO vehicle 200 and the oncoming vehicle 210 on a parallel opposite lane of the carriageway 300 are travelling towards each other at a speed of 20 km/h. The real basic scenario is recorded digitally without selected traffic conditions 310, in this case real rain. In the reference scenario of step 130, the base scenario with the real rain was digitally recorded, which is then compared with the test scenario of step 120. In the test scenario, the rule was added digitally, for example through digital noise and changes in brightness. A correlation between the data of the test scenario and the data of the reference scenario is finally analysed, i.e. it is examined whether the data is suitable for providing the at least one sensor used with the same situation image. If this is the case, the test data can be evaluated as valid and used for further sensor tests, for example to optimise sensor performance.

The data augmentation process described above can be used to generate test stimuli. However, in order to generate valid test results that reflect the behaviour of the sensor algorithms in the real world, an argument for the validity of the augmented data must be provided. This argument can be based on representative sample validations that compare the correlation of the augmented data with real-world data. For this, exactly the same scenarios (augmented and real world) must be available. Due to the high reproducibility capabilities, exact replicas of augmented scenarios can be created with established test sites to provide reliable data for the correlation analysis.

### LIST OF REFERENCE SIGNS

100 Method for validating digitally augmented test scenarios
110 Recording a basic scenario
120 Recording of an extended test scenario
130 Recording a reference scenario
140 Analysing the correlation between test and reference data
150 Evaluation of the validity of sensor data from test scenario
200 EGO (autonomous) vehicle
210 Another vehicle
300 Track
310 Selected traffic conditions in the reference scenario
310′ Selected traffic conditions in the test scenario

1. A method for validating digitally manipulated test scenarios, comprising the steps of:
a. digital recording of a basic scenario, with at least one real vehicle on a real track under defined real traffic conditions;
b. digital recording of the base scenario manipulated by selected traffic conditions to create a reference scenario;
c. manipulating the data of the digitally recorded basic scenario by selected traffic conditions to create an extended test scenario;
d. recording data of the traffic conditions in the extended test scenario and the reference scenario with at least one sensor;
e. analysing the correlation between the test and reference data collected by the at least one sensor, and
f. evaluating a validity of the data of the test scenario based on a result of analysing the correlation.

2. Method according to claim 1,
wherein,
the traffic conditions comprise at least one of: weather conditions, track conditions, objects, or regulations; wherein,
the weather conditions comprising at least one of: precipitation or lighting conditions;
the track conditions comprising at least one of: the type, course, or nature of a track;
the objects comprise at least one of: a vehicles or a person; and
the regulations comprise at least one of: a traffic sign or a light signal.

3. The method according to claim 1,
wherein,
the selected traffic conditions comprise adding the effect of precipitation.

4. The method according to claim 3,
wherein,
the precipitation comprises at least one of: fog, drizzle, rain showers, sleet or snow.

5. A method according to claim 1,
wherein,
a digital noise and brightness changes are added to generate the effect of selected traffic conditions.

6. Method according to claim 1,
wherein,
the selected traffic conditions comprise adding the effect of further objects, such as further vehicles and/or persons.

7. Method according to claim 1,
wherein,
the digitised recording of the base and/or reference scenario comprises imaging and/or distance providing data.

8. Method according to claim 1,
wherein,
in order to assess the validity of the data of the test scenario, compliance with ISO 21448 standard is established.

9. Method according to claim 1,
wherein,
starting from the evaluation of a validity of the data of the test scenario, the data of the selected traffic conditions are manipulated.

10. Method according to claim 1,
wherein,
starting from the analysis of the correlation between the data of the test scenario and those of the reference scenario, detection-related algorithms of the at least one sensor for autonomous vehicles are manipulated.

11. Method according to claim 1,
wherein,
the digitally manipulated test scenarios are augmented test scenarios.

12. A computer-implemented method according to claim 1
for validating digitally manipulated test scenarios,
wherein a computer communicates with at least one image and/or distance providing sensor to record a base and reference scenario, and manipulates the base scenario by selected traffic conditions to create an augmented test scenario, communicates with the at least one sensor to acquire data of the traffic conditions in the reference scenario and the extended test scenario, and analyses and evaluates a correlation between the data acquired by the at least one sensor in the test scenario and the data of the traffic conditions acquired by the at least one sensor in the reference scenario.

13. The computer-implemented method according to claim 12,
wherein,
for evaluating the validity of the data of the test scenario, compliance with the standard ISO 21448-2022 is determined.

14. Computer-implemented method according to claim 12,
wherein,
the data of the selected traffic conditions are manipulated on the basis of the evaluation of a validity of the data of the test scenario.

15. Computer-implemented method according to claim 12,
wherein,
starting from the analysis, detection-related algorithms of the at least one sensor for autonomous vehicles are manipulated.

16. Computer-implemented method according to claim 12,
wherein,
a self-learning algorithm supports an optimisation of at least one of the test scenario or the detection-related algorithms of the at least one sensor.

17. Computer-implemented method according to claim 16,
wherein,
the self-learning algorithm is based on machine learning neural networks.

18. Use of the method according to claim 1 for optimising extended test scenarios and/or sensors for autonomous driving systems.
